(19) United States
(12) Patent Application Publication
(10) Pub. No.: US 2026/0247556 A1
(43) Pub. Date: Aug. 20, 2026

(54) ELECTRONIC DEVICE

(71) Applicant: Panasonic Intellectual Property Management Co., Ltd., Osaka (JP)

(72) Inventors: YUICHI TASHIRO, Kyoto (JP); KIYOSHI WAKINAKA, Osaka (JP); FUMIAKI OZAKI, Hyogo (JP); HIRONORI ICHINOHASHI, Shiga (JP)

(21) Appl. No.: 19/160,523

(22) PCT Filed: Mar. 1, 2024
(86) PCT No.: PCT/JP2024/007697

§ 371 Date: Aug. 28, 2025

(30) Foreign Application Priority Data
Mar. 23, 2023 (JP) 2023-047326

(51) Int. Cl. H05K 5/06; H05K 5/00; H05K 5/02

(52) U.S. Cl. CPC H05K 5/063; H05K 5/0047; H05K 5/0069; H05K 5/0217; H05K 5/0247

(57) ABSTRACT

An electronic device includes a housing and a circuit unit. The circuit unit includes a connector electrically connected to an electronic circuit. The housing includes a first case body including a top plate part and a second case body including a bottom plate part. A first outer peripheral edge of the top plate part includes a first connection side, and a second outer peripheral edge of the bottom plate part includes a second connection side. A connection surface is disposed between the first connection side and the second connection side and exposes the connector. The first case body includes a first side plate part, and the second case body includes a second side plate part. The first side plate part surrounds an outer side of the second side plate part. The top plate part includes a main recessed groove that is disposed in an end part close to the first connection side and traverses the top plate part along the first connection side.

### TECHNICAL FIELD

The present disclosure relates generally to an electronic device, and more particularly to an electronic device including a housing and a circuit unit housed in the housing.

### BACKGROUND

PTL 1 discloses an electrical connection box including a connector-attached substrate including a circuit board and a connector fixed to the circuit board and fitted to a mating connector, a waterproof member assembled to the connector-attached substrate, and a case that houses the connector-attached substrate inside. The case includes a case side wall that surrounds the circuit board and has an opening for allowing the connector to face outside. The waterproof member includes a waterproof part that covers a periphery of a fitting surface of the connector facing the mating connector, and the waterproof part includes a waterproof wall that covers a periphery of the connector or the mating connector.

### CITATION LIST

### Patent Literature

PTL 1: International Publication No. 2019/244511

### SUMMARY

An electronic device according to one aspect of the present disclosure includes a housing and a circuit unit housed in the housing. The circuit unit includes an electronic circuit and a connector electrically connected to the electronic circuit. The housing includes a first case body including a top plate part and a second case body including a bottom plate part facing the top plate part with a space between the top plate part and the bottom plate part. A first outer peripheral edge of the top plate part includes a first connection side that is a part of the first outer peripheral edge. A second outer peripheral edge of the bottom plate part includes a second connection side that is a part of the second outer peripheral edge. The first connection side and the second connection side face each other, and the housing includes a connection surface between the first connection side and the second connection side, the connection surface exposing the connector. The first case body includes a first side plate part extending toward the bottom plate part from a part other than the first connection side in the first outer peripheral edge of the top plate part. The second case body includes a second side plate part extending toward the top plate part from a part other than the second connection side in the second outer peripheral edge of the bottom plate part. The first side plate part is disposed to surround an outer side of the second side plate part. The top plate part includes a main recessed groove disposed in an end part closer to the first connection side than a center of the top plate part, the main recessed groove traverses the top plate part along the first connection side.

An electronic device according to another aspect of the present disclosure includes a housing, a circuit unit having an electronic circuit, and a connector electrically connected to the electronic circuit. The circuit unit and the connector are housed in the housing. The housing has a connection surface that exposes the connector. The housing includes a first case body including a top plate part and a second case body including a bottom plate part facing the top plate part with a space between the top plate part and the bottom plate part. A first outer peripheral edge of the top plate part includes a first connection side that is a part of the first outer peripheral edge. A second outer peripheral edge of the bottom plate part includes a second connection side that is a part of the second outer peripheral edge. The connection surface is located between the first connection side of the top plate part and the second connection side of the bottom plate part. The first case body includes a first side plate part extending toward the bottom plate part from a part other than the first connection side in the first outer peripheral edge of the top plate part. The second case body includes a second side plate part extending toward the top plate part from a part other than the second connection side in the second outer peripheral edge of the bottom plate part. The first side plate part is disposed to surround an outer side of the second side plate part. The first side plate part is inclined with respect to the top plate part to be located outward as a distance from the top plate part increases.

According to each of the aspects of the present disclosure, when water adheres to the housing of the electronic device, the occurrence of a malfunction of the electronic device due to water can be reduced.

### BRIEF DESCRIPTION OF THE DRAWINGS

FIG. 1 is an exploded perspective view illustrating an electronic device according to an exemplary embodiment.

FIG. 2 is a perspective view illustrating the electronic device according to the exemplary embodiment.

FIG. 3 is a plan view illustrating the electronic device according to the exemplary embodiment.

FIG. 4 is a side view illustrating the electronic device according to the exemplary embodiment.

FIG. 5 is a cross-sectional view illustrating only a housing in the electronic device according to the exemplary embodiment taken along line Y-Y in FIG. 3.

FIG. 6 is a cross-sectional view illustrating only the housing in the electronic device according to the exemplary embodiment taken along line X-X in FIG. 3.

FIG. 7 is a cross-sectional view illustrating only the housing in the electronic device according to the exemplary embodiment taken along line Z-Z in FIG. 3.

### DESCRIPTION OF EMBODIMENT

An object of the present disclosure is to provide an electronic device that includes a housing and a circuit unit housed in the housing, and can reduce the occurrence of a malfunction of the electronic device due to water when the water adheres to the housing in the electronic device.

### 1. Overview

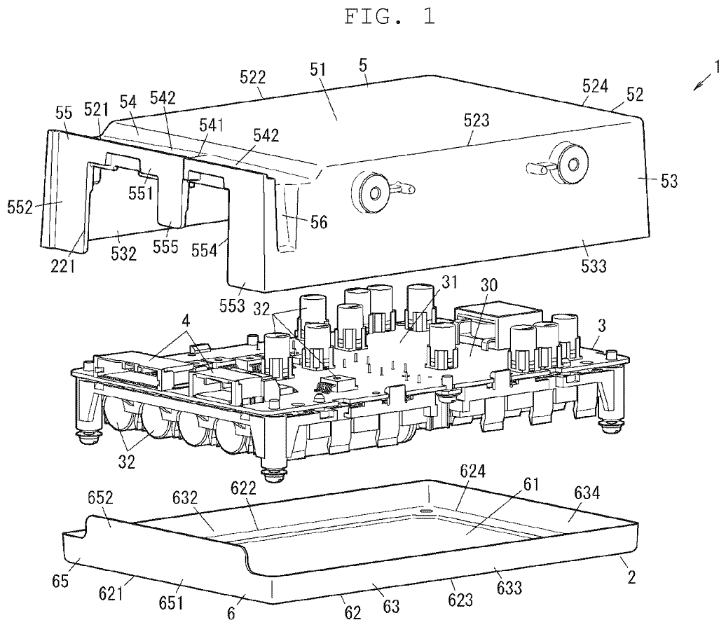

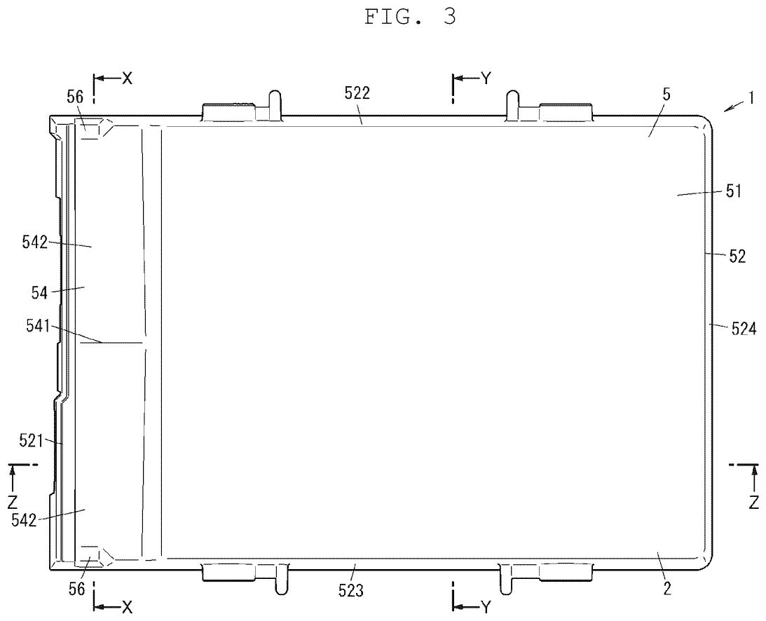

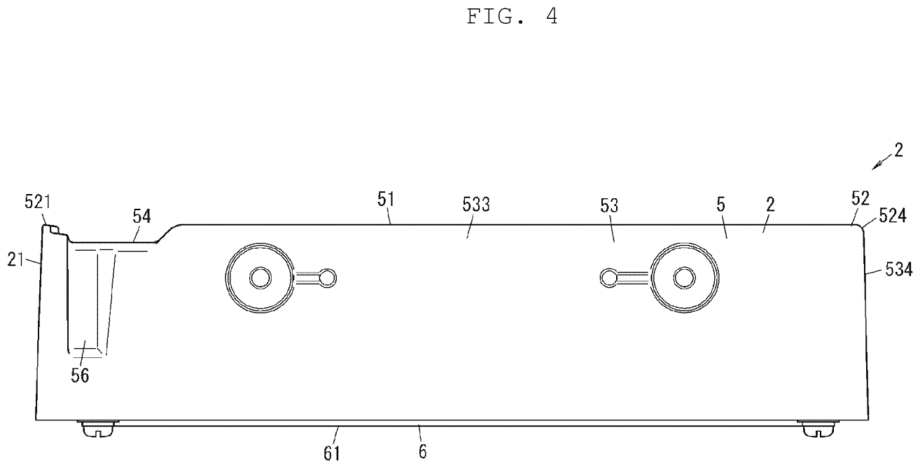

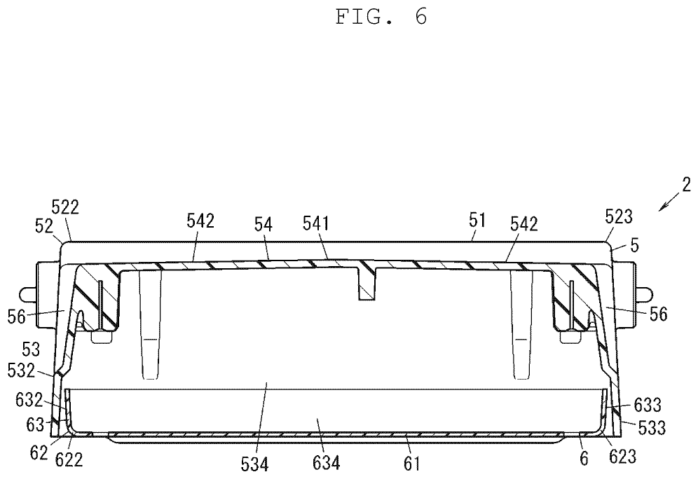

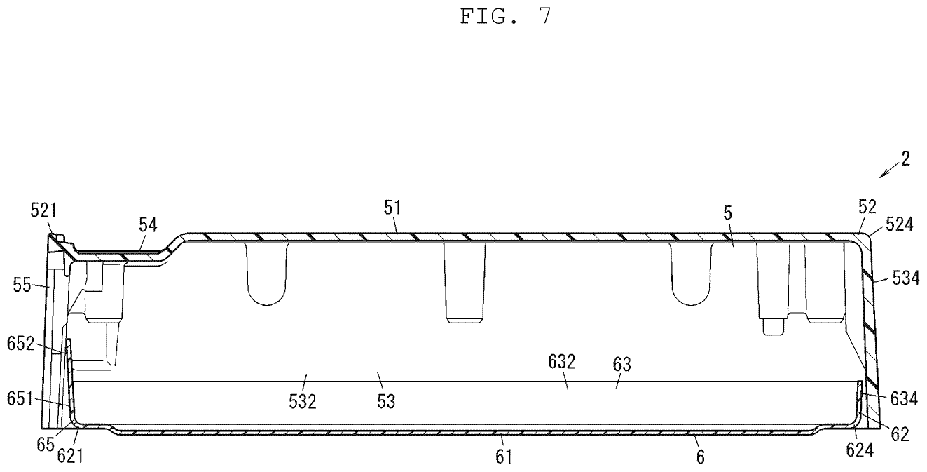

Exemplary embodiments and modifications will be described with reference to FIG. 1 to FIG. 7. However, the exemplary embodiments and the modifications described below are merely some of various exemplary embodiments of the present disclosure. In addition, the exemplary embodiments and the modifications described below can be variously changed according to the design and the like as long as the object of the present disclosure can be achieved.

The drawings referred to below are all schematic views, and the dimensional ratios of components in the drawings do not necessarily reflect the actual dimensional ratios.

As illustrated in FIGS. 1 to 7, electronic device 1 includes housing 2 and circuit unit 3 housed in housing 2. Circuit unit 3 includes electronic circuit 30 and connectors 4 electrically connected to electronic circuit 30. Housing 2 includes first case body 5 including top plate part 51 and second case body 6 including bottom plate part 61 facing top plate part 51 with a space between top plate part 51 and bottom plate part 61. First outer peripheral edge 52 of top plate part 51 includes first connection side 521 that is a part of first outer peripheral edge 52. Second outer peripheral edge 62 of bottom plate part 61 includes second connection side 621 that is a part of second outer peripheral edge 62. First connection side 521 and second connection side 621 face each other. Housing 2 includes connection surface 21 between first connection side 521 and second connection side 621, and connection surface 21 exposes connectors 4. First case body 5 includes first side plate part 53 extending from a part other than first connection side 521 in first outer peripheral edge 52 of top plate part 51 toward bottom plate part 61. Second case body 6 includes second side plate part 63 extending from a part other than second connection side 621 in second outer peripheral edge 62 of bottom plate part 61 toward top plate part 51. First side plate part 53 is located so as to surround an outer side of second side plate part 63.

Top plate part 51 includes main recessed groove 54 that is disposed in an end part closer to first connection side 521 than the center of top plate part 51 and traverses top plate part 51 along first connection side 521. Therefore, when water adheres to an outer surface of top plate part 51 of housing 2, further moves toward connection surface 21, and reaches main recessed groove 54, the water moves toward first side plate part 53 along main recessed groove 54, and thus the water can be prevented from reaching connection surface 21. Therefore, it is possible to prevent the water from reaching connectors 4, so that a malfunction of electronic device 1 due to the water can be prevented.

First side plate part 53 is inclined with respect to top plate part 51 to extend outward as the distance from top plate part 51 increases. Therefore, even if water adheres to an outer surface of first side plate part 53 of housing 2, water can be prevented from entering housing 2 through a gap between first side plate part 53 and second side plate part 63. As a result, the occurrence of a malfunction of electronic device 1 due to water can be reduced.

### 2. Exemplary Embodiment

FIGS. 1 to 7 illustrate electronic device 1 according to the exemplary embodiment. Electronic device 1 includes housing 2 and circuit unit 3 housed in housing 2 (see FIG. 1).

Circuit unit 3 includes electronic circuit 30 and connectors 4 electrically connected to electronic circuit 30. Specifically, circuit unit 3 includes substrate 31 and component 32 mounted on substrate 31. This substrate 31 and mounted component 32 constitute electronic circuit 30.

Circuit unit 3 according to the exemplary embodiment is a backup power supply unit that supplies power to a load when a main power supply fails. Mounted component 32 in the backup power supply unit includes a plurality of field-effect transistors, a controller that controls the field-effect transistors, a drive circuit that drives the field-effect transistors, and a power storage device such as an electric double layer capacitor. Electronic device 1 according to the exemplary embodiment includes two connectors 4. One connector 4 is connected to an external main power supply, and the other connector 4 is connected to an external load.

Housing 2 includes first case body 5 and second case body 6. First case body 5 includes top plate part 51, second case body 6 includes bottom plate part 61. Top plate part 51 and bottom plate part 61 face each other with a space therebetween.

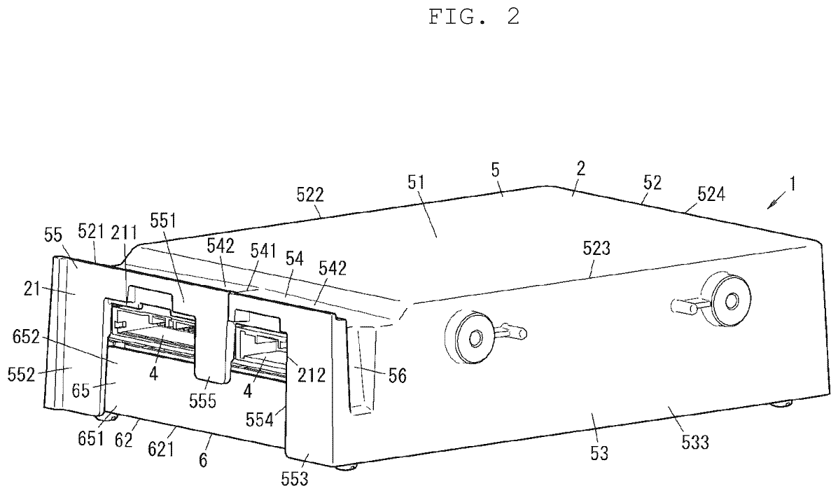

Top plate part 51 of first case body 5 has a flat plate shape and a rectangular shape. Therefore, the outer peripheral edge (first outer peripheral edge 52) of top plate part 51 includes four sides. The four sides are referred to as a first connection side 521, a first right side 522, a first rear side 524, and a first left side 523, respectively (see FIGS. 1 and 2 and the like). First connection side 521 and first rear side 524 face each other, and first right side 522 and first left side 523 face each other. When a direction from bottom plate part 61 to top plate part 51 is defined as an upward direction and a direction from first rear side 524 to first connection side 521 is defined as a forward direction, first left side 523 is disposed at left of first right side 522 and first right side 522 is disposed at right of first left side 523.

Hereinafter, upper, lower, front, rear, left, and right directions are defined with reference to the upward direction and the forward direction. Note that this definition of upper, lower, front, rear, left, and right directions does not intend to limit directions when electronic device 1 is used.

First case body 5 includes first connection plate part 55 extending from first connection side 521 of top plate part 51 toward bottom plate part 61 (that is, downward), and first side plate part 53 extending from a part other than first connection side 521 in first outer peripheral edge 52 of top plate part 51 toward bottom plate part 61 (that is, downward). First side plate part 53 includes two side piece parts (hereinafter, also referred to as first side piece parts) 532, 533 facing each other and first rear piece part 534 facing first connection plate part 55. Among two first side piece parts 532, 533, first side piece part 532 extending from first right side 522 is referred to as first right side piece part 532, and first side piece part 533 extending from first left side 523 is referred to as first left side piece part 533. First rear piece part 534 extends from first rear side 524. A rear end of first right side piece part 532 is connected to a right end of first rear piece part 534, and a rear end of first left side piece part 533 is connected to a left end of first rear piece part 534.

A left end and a right end of first connection plate part 55 are connected to two end parts of first side plate part 53, respectively. That is, the left end of first connection plate part 55 is connected to a front end of first left side piece part 533, and the right end of first connection plate part 55 is connected to a front end of first right side piece part 532.

First connection plate part 55 includes upper frame piece 551 extending downward from first connection side 521, left frame piece 553 extending rightward from a front end edge of first left side piece part 533, and right frame piece 552 extending leftward from a front end edge of first right side piece part 532. First connection plate part 55 has opening 554 surrounded by upper frame piece 551, left frame piece 553, and right frame piece 552 and opened downward. Opening 554 penetrates first connection plate part 55 in the front-rear direction. First connection plate part 55 further includes middle frame piece 555 extending downward from a middle part of upper frame piece 551 in the left-right direction. A lower end of middle frame piece 555 is located above a lower end of each of left frame piece 553 and right frame piece 552.

First side plate part 53 is inclined with respect to top plate part 51 to extend outward as the distance from top plate part 51 increases. It can also be said that an angle formed by the outer surface of top plate part 51 and the outer surface of first side plate part 53 is an obtuse angle. The angle formed by the outer surface of top plate part 51 and the outer surface of first side plate part 53 is, for example, more than or equal to 93° and less than or equal to 95°.

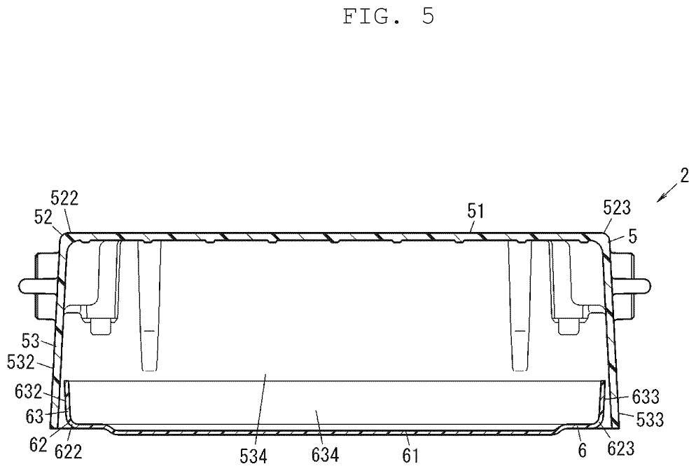

In the exemplary embodiment, each of two first side piece parts 532, 533 (first right side piece part 532 and first left side piece part 533) and first rear piece part 534 constituting first side plate part 53 is inclined with respect to top plate part 51 to extend outward as the distance from top plate part 51 increases (see FIGS. 5 to 7). An angle formed by the outer surface of top plate part 51 and an outer surface of each of two first side piece parts 532, 533 (first right side piece part 532 and first left side piece part 533) and first rear piece part 534 is, for example, more than or equal to 93° and less than or equal to 95°.

First case body 5 includes main recessed groove 54 and two sub recessed grooves 56. Top plate part 51 includes main recessed groove 54 that is disposed in an end part closer to first connection side 521 than the center of top plate part 51 and traverses top plate part 51 along first connection side 521 (see FIGS. 1 to 4 and 7). In addition, first side plate part 53 includes sub recessed groove 56 connected to each of two end parts of main recessed groove 54 (see FIGS. 1 to 4 and 6), and each of sub recessed grooves 56 extends from an end part of main recessed groove 54 toward an end edge of first side plate part 53.

Main recessed groove 54 is disposed in an end part of top plate part 51 that is close to the first connection side 521 and is long along first connection side 521. Main recessed groove 54 is opened at the outer surface of top plate part 51. One of both ends of main recessed groove 54 reaches first left side 523, and the other of both ends of main recessed groove 54 reaches first right side 522. A bottom surface of main recessed groove 54 has a apex 541 located between both ends of main recessed groove 54, and inclined surfaces 542 (two inclined surfaces 542) that are regions extending from apex 541 to each of both ends of main recessed groove 54. Each of inclined surfaces 542 is inclined downward from apex 541 toward a corresponding one of the end parts of main recessed groove 54.

Two first side piece parts 532, 533 (first right side piece part 532 and first left side piece part 533) include respective sub recessed grooves 56. Each of sub recessed grooves 56 is disposed in a corresponding one of end parts of first side piece parts 532, 533 that are close to the first connection side 521. Sub recessed grooves 56 are opened at outer surfaces of first side piece parts 532, 533. An upper end of each of sub recessed grooves 56 is connected to a corresponding one of the end parts of the main recessed groove 54. Each of sub recessed grooves 56 extends from a corresponding one of the end parts of main recessed groove 54 toward a corresponding one of lower end edges of first side piece parts 532, 533. Each of lower ends of sub recessed grooves 56 is located above a corresponding one of the lower end edges of first side piece parts 532, 533. That is, each of the lower ends of sub recessed grooves 56 does not reach a corresponding one of the lower end edges of first side piece parts 532, 533. The opening width of each of sub recessed grooves 56 becomes narrower from a corresponding one of the end parts of main recessed groove 54 toward a corresponding one of the lower end edges of first side piece parts 532, 533. A bottom surface of each of sub recessed grooves 56 is inclined with respect to top plate part 51 to extend outward from a corresponding one of the end parts of main recessed groove 54 toward a corresponding one of the lower end edges of first side piece parts 532, 533.

Bottom plate part 61 of second case body 6 has a flat plate shape and a rectangular shape. Therefore, the outer peripheral edge (second outer peripheral edge 62) of bottom plate part 61 includes four sides. The four sides are referred to as second connection side 621, second right side 622, second rear side 624, and second left side 623, respectively. Second connection side 621 and second rear side 624 face each other, and second right side 622 and second left side 623 face each other. Second left side 623 is disposed at left of second right side 622, that is, second right side 622 is disposed at right f second left side 623.

Second connection side 621, second right side 622, second rear side 624, and second left side 623 of second case body 6 respectively face first connection side 521, first right side 522, first rear side 524, and first left side 523 of first case body S in the vertical direction.

Second case body 6 includes second connection plate part 65 extending from second connection side 621 of bottom plate part 61 toward top plate part 51 (that is, upward), and second side plate part 63 extending from a part other than second connection side 621 in second outer peripheral edge 62 of bottom plate part 61 toward top plate part 51 (that is, upward). Second side plate part 63 includes two second side piece parts 632, 633 facing each other and second rear piece part 634 facing second connection plate part 65. Among two second side piece parts 632, 633, second side piece part 632 extending from second right side 622 is referred to as second right side piece part 632, and second side piece part 633 extending from second left side 623 is referred to as second left side piece part 633. Second rear piece part 634 extends from second rear side 624. A rear end of second right side piece part 632 is connected to a right end of second rear piece part 634, and a rear end of second left side piece part 633 is connected to a left end of second rear piece part 634.

A left end and a right end of second connection plate part 65 are connected to two end parts of second side plate part 63, respectively. That is, the left end of second connection plate part 65 is connected to a front end of second left side piece part 633, and the right end of second connection plate part 65 is connected to a front end of second right side piece part 632.

A vertical dimension of second connection plate part 65 and a vertical dimension of second side plate part 63 in second case body 6 are less than a vertical dimension of first connection plate part 55 and a vertical dimension of first side plate part 53 in first case body 5.

Second connection plate part 65 includes base piece 651 extending upward from entire second connection side 621, and lower frame piece 652 extending upward from a part of an upper end edge of base piece 651 excluding both left and right end parts.

Second side plate part 63 is inclined with respect to bottom plate part 61 to extend outward as the distance from bottom plate part 61 increases. It can also be said that an angle formed by an outer surface of bottom plate part 61 and an outer surface of second side plate part 63 is an obtuse angle. The angle formed by the outer surface of bottom plate part 61 and the outer surface of second side plate part 63 is, for example, more than or equal to 93° and less than or equal to 95°.

In the exemplary embodiment, each of two second side piece parts 632, 633 (second right side piece part 632 and second left side piece part 633) and second rear piece part 634 constituting second side plate part 63 is inclined with respect to bottom plate part 61 to extend outward as the distance from bottom plate part 61 increases (see FIGS. 5 to 7). The angle formed by the outer surface of bottom plate part 61 and an outer surface of each of two second side piece parts 632, 633 (second right side piece part 632 and second left side piece part 633) and second rear piece part 634 is, for example, more than or equal to 93° and less than or equal to 95°.

First side plate part 53 of first case body 5 is disposed to surround the outer side of second side plate part 63 of second case body 6. That is, first left side piece part 533 is located outside second left side piece part 633, first right side piece part 532 is located outside second right side piece part 632, and first rear piece part 534 is located outside second rear piece part 634. First connection plate part 55 is located outside second connection plate part 65. Thus, a space between top plate part 51 and bottom plate part 61 is surrounded by first side plate part 53, second side plate part 63, first connection plate part 55, and second connection plate part 65. Circuit unit 3 is housed in this space.

A gap is present between first side plate part 53 and second side plate part 63 (see FIGS. 5 to 7). Therefore, it is easy to configure housing 2 by combining first case body 5 and second case body 6. When vibration is applied to electronic device 1, generation of sound at a butted part between first side plate part 53 and second side plate part 63 can be prevented.

The end (that is, the lower end) of sub recessed groove 56 disposed opposite to top plate part 51 is located at a position (that is, an upper position) closer to top plate part 51 than end (that is, the upper end) of each of second right side piece part 632 and second left side piece part 633 (see FIG. 5), which is located at a side opposite to bottom plate part 61, is. Therefore, when first case body S and second case body 6 are combined to constitute housing 2, sub recessed grooves 56 do not interfere with second right side piece part 632 and second left side piece part 633.

First connection plate part 55 and second connection plate part 65 constitute connection surface 21 (see FIG. 2). Connection surface 21 is located between first connection side 521 and second connection side 621. Connection surface 21 exposes connectors 4. First connection plate part 55 is located outside second connection plate part 65. The lower end of middle frame piece 555 of first connection plate part 55 is located below an upper end of lower frame piece 652 of second connection plate part 65. Therefore, connection surface 21 has opening 211 (first opening 211) and opening 212 (second opening 212). Opening 211 (first opening 211) is surrounded by upper frame piece 551, right frame piece 552, and middle frame piece 555 of first connection plate part 55 and lower frame piece 652 of second connection plate part 65. And opening 212 (second opening 212) is surrounded by upper frame piece 551, left frame piece 553, and middle frame piece 555 of first connection plate part 55 and lower frame piece 652 of second connection plate part 65. Two connectors 4 are exposed to the outside of housing 2 through first opening 211 and second opening 212, respectively. That is, an external plug can be inserted into each of connectors 4 through a corresponding one of first opening 211 and second opening 212.

Further, the end (that is, the lower end) of each of sub recessed grooves 56 that is disposed opposite to the top plate part 51 is located at a position (that is, lower position) farther from top plate part 51 than connectors 4 are (see FIG. 2 and the like). That is, the end of each of sub recessed grooves 56 that is disposed opposite to top plate part 51 is located at a position farther from top plate part 51 than an end of each of connectors 4 and openings 211, 212, which are located at a side opposite to bottom plate part 61, is.

In electronic device 1 according to the exemplary embodiment, in its use state, for example, the outer surface of bottom plate part 61 is disposed so as not to face upward or obliquely upward in the vertical direction. Even if water drops onto electronic device 1 from above and adheres to the outer surface of housing 2, the movement of the water on the outer surface of housing 2 is controlled, so that the water can be prevented from reaching connectors 4 and entering housing 2. Therefore, the occurrence of a malfunction of electronic device 1 due to water can be reduced.

Specifically, for example, electronic device 1 is disposed such that the outer surface of top plate part 51 faces upward in the vertical direction, or that connection surface 21 faces obliquely downward and the outer surface of top plate part 51 faces obliquely upward. Even if water drops from above electronic device 1 and adheres to the outer surface of top plate part 51, and the water moves toward connection surface 21, when the water reaches the main recessed groove 54, the water is guided by the main recessed groove 54 to first side plate part 53, specifically, first left side piece part 533 or second right side piece part 632. Since main recessed groove 54 has inclined surfaces 542, the movement of water is promoted. Therefore, the water hardly reaches connection surface 21. The water that has reached first side plate part 53 by main recessed groove 54 further moves in sub recessed grooves 56. Therefore, the water is prevented from reaching connection surface 21 along first side plate part 53. Since each of the opening widths of sub recessed grooves 56 decreases as the distance from main recessed groove 54 increases, the movement of water in sub recessed grooves 56 in a direction away from the main recessed groove 54 can be promoted. As described above, the end of each of sub recessed grooves 56 that is disposed opposite to top plate part 51 is located at a position farther from top plate part 51 than an end of a corresponding one of connectors 4 and openings 211, 212, which are disposed opposite to top plate part 51, is. Therefore, even if water reaches connection surface 21 along first left side piece part 533 or second right side piece part 632 after reaching the ends of sub recessed grooves 56, the water reaches below connectors 4 and openings 211, 212. Therefore, the water hardly reaches connectors 4 and openings 211, 212. Even if water moves from top plate part 51 toward first side plate part 53 (that is, first left side piece part 533, first right side piece part 532, or first rear piece part 534), the water drops downward while moving through first side plate part 53. Since the outer surface of first side plate part 53 is inclined as described above, the movement of water in first side plate part 53 is promoted, and drainage at the end edge of first side plate part 53 is favorable. Therefore, the entry of water into housing 2 through the gap between first side plate part 53 and second side plate part 63 is prevented. Further, since second side plate part 63 is inclined as described above, the entry of water into housing 2 is also prevented by this inclination.

Electronic device 1 may be disposed such that, in its use state, an outer surface of one (first left side piece part 533 or first right side piece part 532) of two first side piece parts 532, 533 of first case body 5 faces upward in the vertical direction, or an outer surface of one (first left side piece part 533 or first right side piece part 532) of two first side piece parts 532, 533 faces obliquely upward while connection surface 21 faces obliquely downward. Even if water drops from above electronic device 1 and adheres to first side piece part 532 or 533 and the water moves toward connection surface 21, when the water reaches the sub recessed grooves 56, the water is guided by the sub recessed grooves 56 to top plate part 51. Since the bottom surfaces of sub recessed groove 56 are inclined, the movement of water is promoted. Therefore, the water hardly reaches connection surface 21. The water that has reached top plate part 51 by sub recessed grooves 56 further moves in main recessed groove 54. Therefore, water is prevented from reaching connection surface 21 along top plate part 51. Even if water moves from first side piece part 532 or 533 toward top plate part 51 or first rear piece part 534, the water moves on top plate part 51 or first rear piece part 534 and drops downward. Since the outer surfaces of first side piece parts 532, 533 are inclined as described above, water hardly moves from the outer surface of first side piece part 532 or 533 toward bottom plate part 61. Since second side plate part 63 is inclined as described above, even if water moves from the outer surface of first side piece part 532 or 533 toward bottom plate part 61, the entry of the water into housing 2 is prevented by this inclination.

Electronic device 1 may be disposed such that the outer surface of first rear piece part 534 of first case body 5 faces substantially upward in the vertical direction in the use state. Since first rear piece part 534 is inclined as described above, even if water drops from above electronic device 1 and adheres to first rear piece part 534, the water hardly moves from the outer surface of first rear piece part 534 toward bottom plate part 61. Since second side plate part 63 is inclined as described above, even if water moves from the outer surface of first rear piece part 534 toward bottom plate part 61, the entry of the water into housing 2 is prevented by this inclination. Since connection surface 21 faces downward, when water moves from first rear piece part 534 to each of top plate part 51, first left side piece part 533, and first right side piece part 532, the water easily drops from electronic device 1 without reaching connection surface 21. Therefore, water can be prevented from reaching connectors 4.

### 3. Modifications

Although circuit unit 3 is a backup power supply unit in the exemplary embodiment, circuit unit 3 may be a unit having an appropriate function other than the backup power supply unit. For example, circuit unit 3 may be a regulator unit, a DC/DC converter unit, an inverter unit, or the like.

In the exemplary embodiment, top plate part 51 and bottom plate part 61 have a rectangular shape, but top plate part 51 and bottom plate part 61 may have an appropriate shape other than the rectangular shape.

In the exemplary embodiment, top plate part 51 has main recessed groove 54, and first side plate part 53 is inclined with respect to top plate part 51 to extend outward as the distance from top plate part 51 increases. However, top plate part 51 may not have main recessed groove 54, and first side plate part 53 may be inclined with respect to top plate part 51 to extend outward as the distance from top plate part 51 increases. Only by first side plate part 53 having an inclination, an effect that water hardly enters the inside of housing 2 can be obtained. Top plate part 51 may have main recessed groove 54, and first side plate part 53 may not be inclined outward as the distance from top plate part 51 increases. The effect that water hardly reaches connectors 4 can be obtained only by top plate part 51 having main recessed groove 54.

### 4. Aspects

An electronic device according to a first aspect of the present disclosure includes a housing (2) and a circuit unit (3) housed in the housing (2). The circuit unit (3) includes an electronic circuit (30) and a connector (4) electrically connected to the electronic circuit (30). The housing (2) includes a first case body (5) including a top plate part (51) and a second case body (6) including a bottom plate part (61) facing the top plate part (51) with a space between the top plate part (51) and the bottom plate part (61). A first outer peripheral edge (52) of the top plate part (51) includes a first connection side (521) that is a part of the first outer peripheral edge (52). A second outer peripheral edge (62) of the bottom plate part (61) includes a second connection side (621) that is a part of the second outer peripheral edge (62). The first connection side (521) and the second connection side (621) face each other, and the housing (2) includes a connection surface (21) between the first connection side (521) and the second connection side (621), the connection surface exposing the connector (4). The first case body (5) includes a first side plate part (53) extending from a part other than the first connection side (521) in the first outer peripheral edge (52) of the top plate part (51) toward the bottom plate part (61). The second case body (6) includes a second side plate part (63) extending from a part other than the second connection side (621) in the second outer peripheral edge (62) of the bottom plate part (61) toward the top plate part (51). The first side plate part (53) is disposed to surround an outer side of the second side plate part (63). The top plate part (51) includes a main recessed groove (54) disposed in an end part closer to the first connection side (521) than a center of the top plate part (51), the main recessed groove (54) traversing the top plate part (51) along the first connection side (521).

According to this aspect, even if water adheres to an outer surface of the housing (2), the movement of the water can be controlled by the main recessed groove (54), so that the water can be prevented from reaching the connector (4).

According to a second aspect, in the first aspect, the first side plate part (53) has a sub recessed groove (56) connected to each of two end parts of the main recessed groove (54), and the sub recessed groove (56) extends from the end parts of the main recessed groove (54) toward an end edge of the first side plate part (53).

According to this aspect, the movement of water can also be controlled by the sub recessed groove (56), so that water can be prevented from reaching the connector (4).

According to a third aspect, in the second aspect, an end part of the sub recessed groove (56) is located at a position farther from the top plate part (51) than the connector (4) is, the end part of the sub recessed groove (56) being disposed opposite to the top plate part (51).

According to this aspect, water that has reached the end parts of the sub recessed groove (56) can be prevented from reaching the connector (4).

In a fourth aspect, in the second or third aspect, the first side plate part (53) has two side piece parts (532, 533) facing each other. Each of the two side piece parts (532, 533) includes the sub recessed groove (56). The side piece parts (532, 533) are inclined with respect to the top plate part (51) to extend outward as a distance from the top plate part (51) increases.

According to this aspect, the movement of water can also be controlled by a combination of the inclination of the side piece parts (532, 533) and the sub recessed grooves (56), so that water can be prevented from reaching the connector (4).

According to a fifth aspect, in any one of the second to fourth aspects, an opening width of the sub recessed groove (56) decreases as a distance from the main recessed groove (54) increases.

According to this aspect, since the movement of water in the sub recessed groove (56) is promoted, it is possible to further prevent water from reaching the connector (4).

According to a sixth aspect, in any one of the first to fifth aspects, the first side plate part (53) is inclined with respect to the top plate part (51) to extend outward as a distance from the top plate part (51) increases.

According to this aspect, the movement of water is controlled by the inclination of the first side plate part (53), and the entry of water into the housing (2) can be prevented.

An electronic device (1) according to a seventh aspect includes a housing (2), a circuit unit (3) including an electronic circuit (30), and a connector (4) electrically connected to the electronic circuit (30). The circuit unit (3) and the connector (4) are housed in the housing (2). The housing (2) includes a connection surface (21) that exposes the connector (4). The housing (2) includes a first case body (5) including a top plate part (51) and a second case body (6) including a bottom plate part (61) facing the top plate part (51) with a space between the top plate part (51) and the bottom plate part (61). A first outer peripheral edge (52) of the top plate part (51) includes a first connection side (521) that is a part of the first outer peripheral edge (52). A second outer peripheral edge (62) of the bottom plate part (61) includes a second connection side (621) that is a part of the second outer peripheral edge (62). The connection surface (21) is located between the first connection side (521) of the top plate part (51) and the second connection side (621) of the bottom plate part (61). The first case body (5) includes a first side plate part (53) extending from a part other than the first connection side (521) in the first outer peripheral edge (52) of the top plate part (51) toward the bottom plate part (61). The second case body (6) includes a second side plate part (63) extending from a part other than the second connection side (621) in the second outer peripheral edge (62) of the bottom plate part (61) toward the top plate part (51). The first side plate part (53) is disposed to surround an outer side of the second side plate part (63). The first side plate part (53) is inclined with respect to the top plate part (51) to extend outward as a distance from the top plate part (51) increases.

According to this aspect, even if water adheres to an outer surface of the housing (2), the movement of water can be controlled by the inclination of the first side plate part (53), and the entry of the water into the housing (2) can be prevented.

According to an eighth aspect, in the sixth or seventh aspect, the second side plate part (63) is inclined with respect to the bottom plate part (61) to extend outward as a distance from the bottom plate part (61) increases.

According to this aspect, the movement of water is controlled by the inclination of the second side plate part (63), and the entry of the water into the housing (2) can be prevented.

### REFERENCE MARKS IN THE DRAWINGS

1: electronic device
2: housing
21: connection surface
3: circuit unit
30: electronic circuit
31: substrate
32: mounted component
4: connector
5: first case body
51: top plate part
52: first outer peripheral edge
521: first connection side
53: first side plate part
532: side piece part (first right side piece part)
533: side piece part (first left side piece part)
54: main recessed groove
56: sub recessed groove
6: second case body
61: bottom plate part
62: second outer peripheral part
621: second connection side
63: second side plate part

1. An electronic device comprising:
a housing; and
a circuit unit housed in the housing, wherein:
the circuit unit includes:
an electronic circuit; and
a connector electrically connected to the electronic circuit,
the housing includes:
a first case body including a top plate part; and
a second case body including a bottom plate part facing the top plate part with a space between the top plate part and the bottom plate part,
a first outer peripheral edge of the top plate part includes a first connection side that is a part of the first outer peripheral edge,
a second outer peripheral edge of the bottom plate part includes a second connection side that is a part of the second outer peripheral edge,
the first connection side and the second connection side face each other,
the housing includes a connection surface between the first connection side and the second connection side, the connection surface exposing the connector,
the first case body includes a first side plate part extending toward the bottom plate part from a part other than the first connection side in the first outer peripheral edge of the top plate part,
the second case body includes a second side plate part extending toward the top plate part from a part other than the second connection side in the second outer peripheral edge of the bottom plate part,
the first side plate part is disposed to surround an outer side of the second side plate part, and
the top plate part includes a main recessed groove disposed in an end part closer to the first connection side than a center of the top plate part, the main recessed groove traversing the top plate part along the first connection side.

2. The electronic device according to claim 1, wherein:
the first side plate part includes a sub recessed groove connected to each of two end parts of the main recessed groove, and
the sub recessed groove extends from a corresponding one of the two end parts of the main recessed groove toward an end edge of the first side plate part.

3. The electronic device according to claim 2, wherein an end part of the sub recessed groove is located at a position farther from the top plate part than the connector is, the end part of the sub recessed groove being separated from the top plate part.

4. The electronic device according to claim 1, wherein:
the first side plate part includes two side piece parts facing each other,
each of the two side piece parts includes the sub recessed groove, and
each of the side piece parts is inclined with respect to the top plate part to extend be located outward as a distance from the top plate part increases.

5. The electronic device according to claim 2, wherein an opening width of the sub recessed groove decreases as a distance from the main recessed groove increases.

6. The electronic device according to claim 1, wherein the first side plate part is inclined with respect to the top plate part to be located outward as a distance from the top plate part increases.

7. An electronic device comprising:
a housing;
a circuit unit including an electronic circuit; and
a connector electrically connected to the electronic circuit, wherein:
the circuit unit and the connector are housed in the housing,
the housing includes a connection surface that exposes the connector,
the housing includes a first case body including a top plate part and a second case body including a bottom plate part facing the top plate part with a space between the top plate part and the bottom plate part,
a first outer peripheral edge of the top plate part includes a first connection side that is a part of the first outer peripheral edge,
a second outer peripheral edge of the bottom plate part includes a second connection side that is a part of the second outer peripheral edge,
the connection surface is located between the first connection side of the top plate part and the second connection side of the bottom plate part,
the first case body includes a first side plate part extending toward the bottom plate part from a part other than the first connection side in the first outer peripheral edge of the top plate part,
the second case body includes a second side plate part extending toward the top plate part from a part other than the second connection side in the second outer peripheral edge of the bottom plate part,
the first side plate part is disposed to surround an outer side of the second side plate part, and
the first side plate part is inclined with respect to the top plate part to extend be located outward as a distance from the top plate part increases.

8. The electronic device according to claim 6, wherein the second side plate part is inclined with respect to the bottom plate part to be located outward as a distance from the bottom plate part increases.
